(19) United States
(12) Patent Application Publication
(10) Pub. No.: US 2006/0216863 A1
(43) Pub. Date: Sep. 28, 2006

(54) Method of manufacturing semiconductor device

(75) Inventor: Hideyuki Arakawa, Tokyo (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: Renesas Technology Corp., Tokyo (JP)

(21) Appl. No.: 11/347,231

(22) Filed: Feb. 6, 2006

(30) Foreign Application Priority Data
Mar. 28, 2005 (JP) 2005-091023

(51) Int. Cl. H01L 21/00

(52) U.S. Cl. 438/118; 438/119

(57) ABSTRACT

A method of manufacturing a semiconductor device includes a step of preparing a first chip having a plurality of first pads and a second chip having a plurality of second pads, a step of forming a first bump electrode on one of the plurality of first pads by a wire fed out from a capillary, a step of forming a first wire electrically connecting one of the first bump electrode and one of the plurality of second pads by the wire fed out from the capillary after the step of forming the first bump electrode, and a step of forming a second bump electrode on another of the plurality of first pads by the wire fed out from the capillary after the step of forming the first wire.

### BACKGROUND OF THE INVENTION

1. Field of the Invention

The present invention relates to a method of manufacturing a semiconductor device in which a bump electrode is formed by a metal wire passed through a capillary and the metal wire is stitch-bonded on the bump electrode.

2. Background Art

FIGS. 9A and 9B are sectional views showing stitch bonding on a lead. As shown in FIG. 9A, a gold wire 12, which is a wire made of a gold alloy, is pressed against a lead 13 by a capillary 11 and is stitch-bonded to the lead 13 by applying ultrasonic vibration to the gold wire 12. When stitch-bonding is performed, the thickness of the gold wire 12 pinched between the capillary 11 and the lead 13 is reduced since the lead 13 is hard. The strength of the gold wire 12 is thereby reduced. Therefore the gold wire 12 can be easily cut (tail-cut) by being pinched in a clamper 14 and pulled upward, as shown in FIG. 9B. In some case, a wire made of a metal other than gold is used as the metal wire.

In a case where a gold wire is directly bonded to an Al pad on a chip, the load on a capillary is concentrated to produce a crack in an SiO₂ interlayer insulating film under the Al pad. For chip-to-chip wire bonding, therefore, a bump electrode is used (see, for example, Japanese Patent Laid-Open No. 2001-15541). For a thin package, reverse bonding using a bump electrode is performed for the purpose of reducing the height of a gold wire.

FIGS. 10A and 10B are sectional views showing conventional bump electrode formation. A bump electrode 17 is first formed on an Al pad 16 on a chip by a gold wire 12 fed out from a capillary 11, as shown in FIG. 10A. Thereafter, the gold wire 12 is cut by being pinched in a clamper 14 and pulled upward, as shown in FIG. 10B.

FIGS. 11A and 11B are sectional views showing conventional stitch bonding of a gold wire on a bump electrode. A gold wire 12 is first pressed against a bump electrode 17 by a capillary 11 and bonded to the bump electrode 17 by applying ultrasonic vibration to the gold wire 12 and by crushing the goldwire 12, as shown in FIG. 1A. Thereafter, the gold wire 12 is cut by being pinched in a damper 14 and pulled upward, as shown in FIG. 11B.

FIGS. 12A and 12B are top views showing a conventional interchip wire method. All of a plurality of bump electrodes 17 are formed, as shown in FIG. 12A. Thereafter, a gold wire 12 is stitch-bonded on each bump electrode 17, as shown in FIG. 12B.

In conventional stitch bonding of a gold wire on a bump electrode, however, the gold wire 12 pinched between the capillary 11 and the bump electrode 17 is not sufficiently crushed and cannot be sufficiently reduced in thickness, because the bump electrode 17 is soft. Therefore the strength of the gold wire 12 is so high that a twist in the gold wire 12 and separation of the bump electrode 17 from the Al pad 16 can be caused by a reaction at the time of cutting of the gold wire 12. Also, a similar phenomenon occurs in the conventional bump electrode formation. As a result of such a phenomenon, electrical short circuit occurs between S-shaped bends in the gold wires 12 due to a twist and the bump electrode 17 is separated to cause electrical opening, resulting in failure to manufacture a highly integrated semiconductor device with stability.

In the case of use of the conventional interchip wire method (FIGS. 12A and 12B) in particular, the length of gold wire 12 consumed for the formation of the bump electrode 17 is short and, therefore, a particular portion of the wire remains in the capillary without being consumed in the process of successively forming bump electrodes 17. The particular portion of gold wire 12 in the capillary is repeatedly twisted by the successively forming bump electrodes 17 to accumulate an amount of twist in the gold wire 12. The length of twisted gold wire 12 is increased to become substantially equal to the length of the capillary, which is about 10 mm. Larger S-shaped bends in gold wires 12 are formed due to this twist. The possibility of short circuit between gold wires 12 is thereby increased.

### SUMMARY OF THE INVENTION

In view of the above-described problem, an object of the present invention is to provide a semiconductor device manufacturing method for manufacturing a highly integrated semiconductor device with stability.

According to the first aspect of the present invention, a method of manufacturing a semiconductor device includes a step of preparing a first chip having a plurality of first pads and a second chip having a plurality of second pads, a step of forming a first bump electrode on one of the plurality of first pads by a wire fed out from a capillary, a step of forming a first wire electrically connecting one of the first bump electrode and one of the plurality of second pads by the wire fed out from the capillary after the step of forming the first bump electrode, and a step of forming a second bump electrode on another of the plurality of first pads by the wire fed out from the capillary after the step of forming the first wire.

According to the second aspect of the present invention, a method of manufacturing a semiconductor device includes a step of preparing a first chip having a plurality of first pads and a plurality of second pads arranged with a pitch smaller than a pitch with which the plurality of first pads are arranged, and a second chip having a plurality of third pads, a step of forming a plurality of first bump electrodes on the plurality of first pads and a plurality of second bump electrodes on the plurality of second pads by a wire fed out from a capillary, a step of forming a plurality of first wires electrically connecting one of the plurality of first bump electrodes and one of the plurality of third pads by the wire fed out from the capillary after the step of forming the plurality of first and second bump electrodes, and a step of forming a plurality of second wires electrically connecting another of the plurality of second bump electrodes and another of the plurality of third pads by the wire fed out from the capillary after the step of forming the plurality of first wires.

According to the third aspect of the present invention, a method of manufacturing a semiconductor device includes a step of forming a bump electrode on a pad by a wire passed through a capillary, a step of laterally moving the capillary at least with an amplitude equal to or larger than a gap between the wire and an inner wall surface of the capillary after the step of forming the bump electrode, and a step of cutting the wire by pinching the wire in a clamper and pulling the wire upward after the step of laterally moving the capillary.

According to the fourth aspect of the present invention, a method of manufacturing a semiconductor device includes a step of stitch bonding a wire on a bump electrode by using a capillary, a step of laterally moving the capillary at least with an amplitude equal to or larger than a gap between the wire and an inner wall surface of the capillary after the stitch bonding step, and a step of cutting the wire by pinching the wire in a clamper and pulling the wire upward after the step of laterally moving the capillary.

Other and further objects, features and advantages of the invention will appear more fully from the following description.

According to the first aspect of the present invention, a twist in the wire due to a reaction to the first tail cutting can be dispersed and, therefore, S-shape bending of the wire can be limited. According to the second aspect of the present invention, electrical short circuit between wires due to S-shaped bends in the wire can be prevented. According to the third or fourth aspect of the present invention, S-shape bending of the wire and separation of the bump electrode can be limited. Thus, the present invention makes it possible to manufacture a highly integrated semiconductor device with stability.

### BRIEF DESCRIPTION OF THE DRAWINGS

FIGS. 1A to 1F are top views showing a method of manufacturing a semiconductor device according to a first embodiment of the present invention.

FIGS. 2A to 2D are corresponding sectional views.

FIG. 3A is a sectional view of an example of a semiconductor device to which the present invention can be applied.

FIG. 3B is a top view of the semiconductor device.

FIG. 4A is a sectional view of another semiconductor device to which the present invention can be applied.

FIG. 4B is a top view of the semiconductor device.

FIG. 5 is a top view showing a method of manufacturing a semiconductor device according to a second embodiment of the present invention.

FIGS. 6A to 6D are sectional views showing a method of manufacturing a semiconductor device according to a third embodiment of the present invention.

FIGS. 7A to 7C are enlarged sectional views showing the tip of the capillary.

FIGS. 8A to 8D are sectional views showing a method of manufacturing a semiconductor device according to a fourth embodiment of the present invention.

FIGS. 9A and 9B are sectional views showing stitch bonding on a lead.

FIGS. 10A and 10B are sectional views showing conventional bump electrode formation.

FIGS. 11A and 11B are sectional views showing conventional stitch bonding of a gold wire on a bump electrode.

FIGS. 12A and 12B are top views showing a conventional interchip wire method.

### DETAILED DESCRIPTION OF THE PREFERRED EMBODIMENTS

### First Embodiment

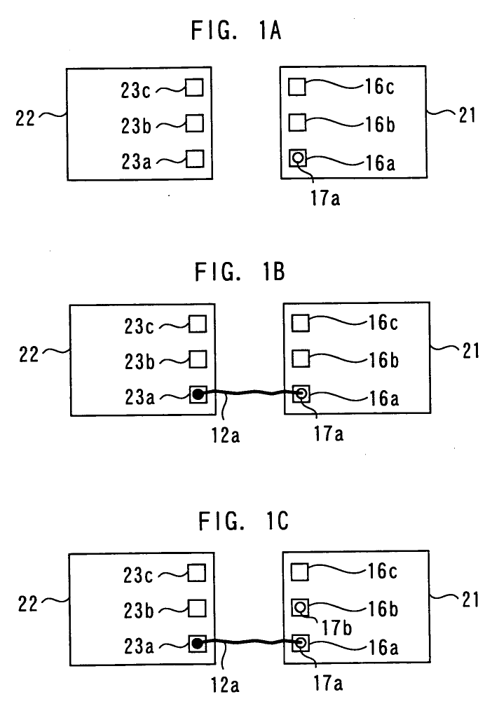

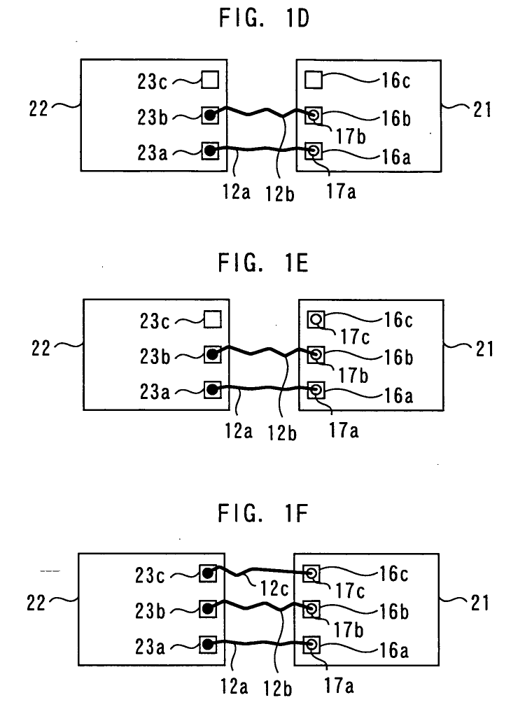

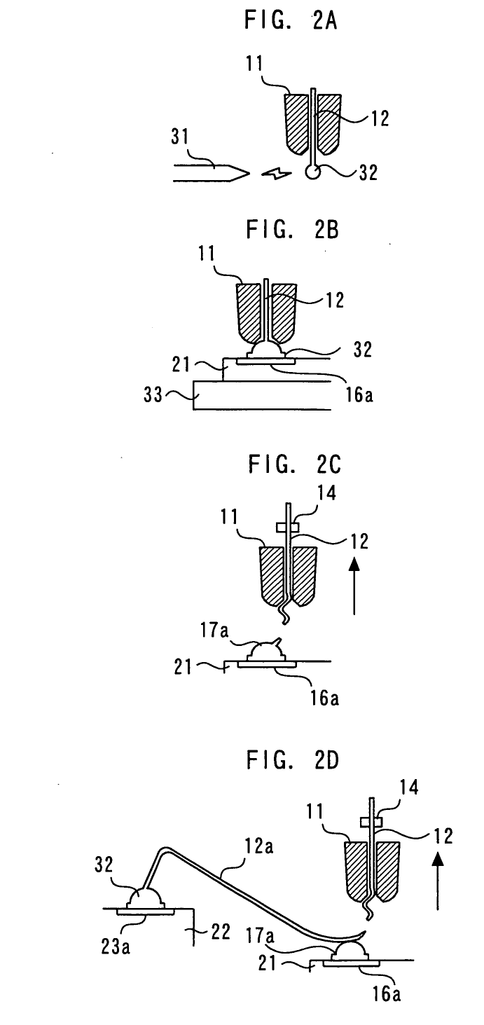

FIGS. 1A to 1F are top views showing a method of manufacturing a semiconductor device according to a first embodiment of the present invention, and FIGS. 2A to 2D are corresponding sectional views.

First, a chip 21 (first chip) having Al pads 16a to 16c (a plurality of first pads) and a chip 22 (second chip) having Al pads 23a to 23c (a plurality of second pads) are prepared, as shown in FIG. 1A. Next, a tip of a gold wire 12 fed out from a capillary 11 is molten by electric discharge from a torch 31 to form a gold ball 32 having a diameter larger than that of the gold wire 12, as shown in FIG. 2A. Thereafter, the gold ball 32 is pressed by the capillary 11 against the Al pad 16a on the chip 21 placed on a stage 33 and the gold ball 32 and the Al pad 16a are joined at the interface therebetween by applying a weight, heat and ultrasound for example, as shown in FIG. 2B. Thereafter, the gold wire 12 above the capillary 11 is pulled by being pinched in a clamper 14 to be cut above the gold ball 32, as shown in FIG. 1A and FIG. 2C. In this way, a bump electrode 17a (first bump electrode) is formed on the Al pad 16a by the gold wire 12 fed out from the capillary 11.

Thereafter, another gold ball 32 is formed as a tip of gold wire 12 fed out of the capillary 11 in the same manner as shown in FIG. 2A and is ball-bonded to the Al pad 23a on the chip 22 by using the capillary 11 (first bonding), as shown in FIGS. 1B and 2D. Thereafter, the gold wire 12 extending from the gold ball 32 is fed out from the capillary 11 until it reaches a position above the bump electrode 17a. The gold wire 12 is then pressed against the bump electrode 17a for 10 ms by the capillary 11 while ultrasonic vibration is applied to the gold wire 12, thereby stitch-bonding on the bump electrode 17a a portion of the gold wire 12 extending from the gold ball 32 (second bonding). The gold wire 12 is then cut (tail-cut) by being pinched in the clamper 14 and pulled upward. In this way, a gold wire 12a (first wire) electrically connecting the bump electrode 17a and the Al pad 23a is formed by the gold wire 12 fed out from the capillary 11.

Thereafter, a bump electrode 17b (second bump electrode) is thereafter formed on the Al pad 16b on the chip 21, as shown in FIG. 1C, that is, in the same manner as shown in FIGS. 1A and 2C. Subsequently, a gold ball formed as a tip of the gold wire 12 is ball-bonded to the Al pad 23b on the chip 22, and the goldwire 12 is thereafter stitch-bonded on the bump electrode 17b, as shown in FIG. 1D. In this way, a gold wire 12b (second wire) electrically connecting the bump electrode 17b and the Al pad 23b is formed by the gold wire 12 fed out from the capillary 11.

Thereafter, a bump electrode 17c is formed on the Al pad 16c on the chip 21, as shown in FIG. 1E. Subsequently, a gold ball formed as a tip of the gold wire 12 is ball-bonded to the Al pad 23c on the chip 22, and the gold wire 12 is thereafter stitch-bonded on the bump electrode 17c, as shown in FIG. 1F, thereby forming a gold wire 12c electrically connecting the bump electrode 17c and the Al pad 23c.

In the first embodiment, as described above, a bump electrode is formed on one of a plurality of Al pads, and a gold wire is stitch-bonded on the bump electrode immediately after the formation of the bump electrode. The same steps are repeatedly performed with respect to the other Al pads. This method ensures that a twist in the gold wire produced by a reaction to the first tail cutting can be dispersed in comparison with the conventional method in which a plurality of bump electrodes are successively formed and bonding of a plurality of gold wires is thereafter performed (FIGS. 12A and 12B). Therefore, the accumulation of an S-shaped bend in the gold wire caused each time a bump electrode is formed can be effectively limited. In the present invention, a wire for connection between chips is formed each time a bump electrode is formed, thereby minimizing the accumulation of an S-shaped bend. However, the present invention is not limited to this. Wires for connection between chips may be formed after successively forming a plurality of bump electrodes. Even in such a case, it is desirable to minimize the number of bump electrodes successively formed, since the accumulation of S-shaped bends in a particular portion of the wire in the capillary is increased if a substantially large number of bump electrodes is successively formed. For example, even a process in which a plurality of bumps are successively formed is organized so that a bump forming step and a wire forming step are performed a certain number of times. This is somewhat advantageously effective in limiting the accumulation of S-shaped bends in a particular portion of the wire in comparison with the method in which wires are formed after successively forming all bumps.

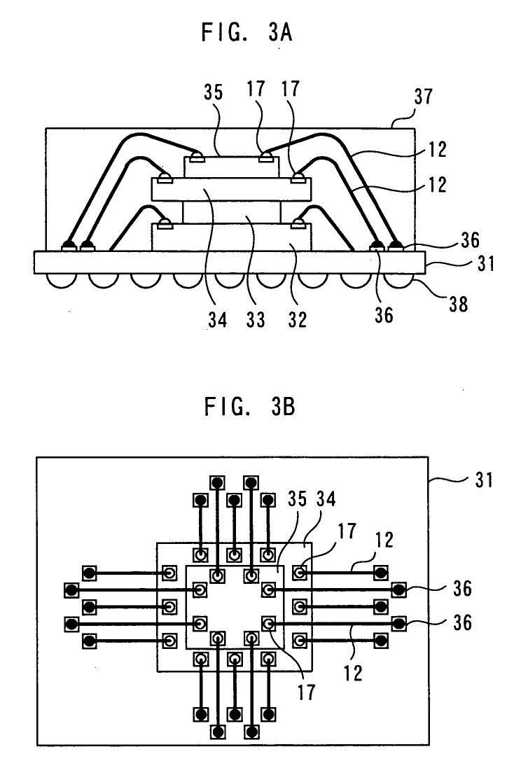

FIG. 3A is a sectional view of an example of a semiconductor device to which the present invention can be applied. FIG. 3B is a top view of the semiconductor device. A chip 32, a spacer chip 33, a chip 34 and a chip 35 are mounted on a glass-epoxy wiring substrate 31. Bump electrodes 17 are formed on each of the chips 34 and 35. Gold wires 12 are ball-bonded to leads 36 and are stitch-bonded on the bump electrode 17. The present invention can be applied to a method of manufacturing such a semiconductor device in which a plurality of bump electrodes are formed on a chip, and in which a plurality of wires to be connected to the bump electrodes on the chip by stitch bonding are formed. Also in such a case, it is undesirable to use a process in which all bump electrodes to be formed on a chip are successively formed and wires to be connected to the chip are thereafter formed. For example, it is preferable to use, for example, a process in which each time a bump electrode is formed, a wire to be connected to the bump electrode is formed, or a process in which a step of forming a plurality of bumps and a step of forming a plurality of wires are repeatedly performed. In the semiconductor device shown in FIG. 3, all the components on the glass-epoxy substrate 31 are encapsulated in a resin 37 and solder balls 38 are formed on the bottom surface of the glass-epoxy substrate 31.

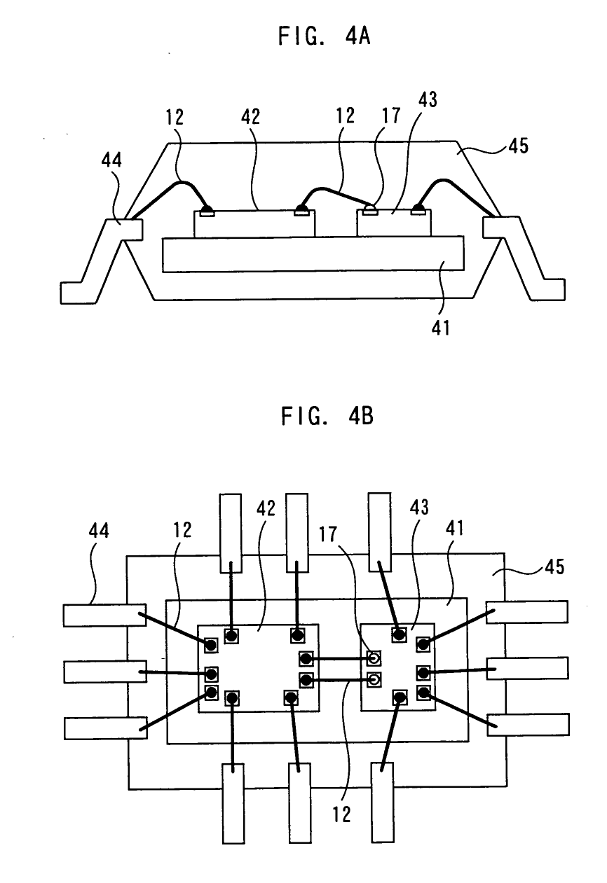

FIG. 4A is a sectional view of another semiconductor device to which the present invention can be applied. FIG. 4B is a top view of the semiconductor device. A chip 42 and a chip 43 are mounted side by side on a die pad 41. Each of the chips 42 and 43 and leads 44 are connected by gold wires 12. Bump electrodes 17 are formed on Al pads on the chip 43. Gold wires 12 are ball-bonded to Al pads on the chip 42 and are stitch-bonded on the bump electrodes 17. The present invention can be applied to this interchip bonding. All the components are encapsulated in a resin 45.

### Second Embodiment

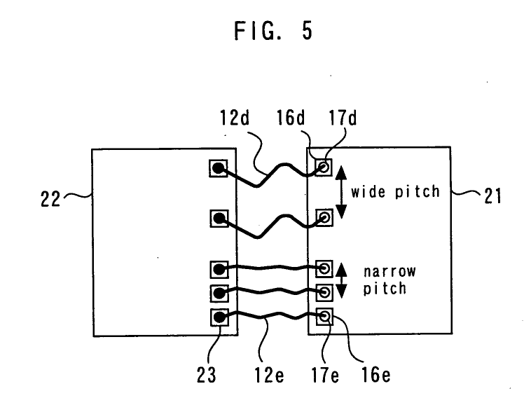

FIG. 5 is a top view showing a method of manufacturing a semiconductor device according to a second embodiment of the present invention. First, a chip 21 (first chip) having a plurality of Al pads 16d (a plurality of first pads) and a plurality of Al pads 16e (a plurality of second pads) arranged with a pitch larger than a pitch with which the plurality of Al pads 16d are arranged and a chip 22 (second chip) having a plurality of Al pads 23 (a plurality of third pads) are prepared, as shown in FIG. 5.

Next, bump electrodes 17d (a plurality of first bump electrodes) are respectively formed on the plurality of Al pads 16d on the chip 21 by a gold wire fed out from the capillary 11, and bump electrodes 17e (a plurality of second bump electrodes) are respectively formed on the plurality of Al pads 16e by the gold wire.

Thereafter, gold wires 12d (a plurality of first wires) which electrically connect one of the plurality of bump electrodes 17d and one of the plurality of Al pads 23 are formed by the wire fed out from the capillary. More specifically, a gold ball formed as a tip of one gold wire 12d is ball-bonded to one of the plurality of Al pads 23 on the chip 22 by using the capillary, and the gold wire 12 is thereafter stitch-bonded on the bump electrode 17d on the corresponding Al pad 16d.

Thereafter, gold wires 12e (a plurality of second wires) which electrically connect another of the plurality of bump electrodes 17e and another of the plurality of Al pads 23 are also formed by the wire fed out from the capillary.

Thus, the wire 12d connected to the pads 16d with the larger adjacent-pad pitch in the plurality of Al pads 16d and 16e on the chip 21 are formed before the formation of the wires 12e connected to the pads 16e with the smaller pitch.

In the case where wires are connected to the plurality of Al pads 16d and 16e on the chip 21 by stitch bonding, bump electrodes 17d and 17e formed of soft gold balls are formed in advance on the Al pads 16d and 16e in order to reduce local stress concentration on the chip in the stitch bonding step. If the plurality of bump electrodes 17d and 17e are successively formed, S-shaped bends produced by bump electrode formation are accumulated in a particular portion of the wire in the capillary 11, and a wire 12d in which large S-shaped bends are produced are formed in the capillary 11, since the amount of consumption of the gold wire is small. If the wire 12d in which large S-shaped bends are produced as described above is used as wires to be connected to the pads 16e with the smaller pitch, the possibility of short circuit between the wires is increased.

In the present invention, therefore, the wire 12d in which large S-shaped bends are accumulated by the successive formation of the bump electrodes 17d and 17e is consumed as wires connected to the pads 16d with the larger pitch to prevent short circuit between the wires 12e connecting the pads 16e with the smaller pitch.

More specifically, it is preferable to set minimum pitches according to loop lengths of gold wires, as shown below, with respect to the Al pads 16e with the larger pitch, to which the gold wire in which twists are accumulated is to be connected.

| loop lengths of gold wires | minimum pitches of Al pads |
|---|---|
| 0.4˜5.0 mm | more than 150 μm |
| 0.4˜2.5 mm | more than 100 μm |
| 0.4˜1.8 mm | more than 70 μm |

The second embodiment and the first embodiment may be combined to limit S-shaped bends in the gold wire. The combination of the first and second embodiments ensures that short circuit between gold wires can be prevented more reliably.

### Third Embodiment

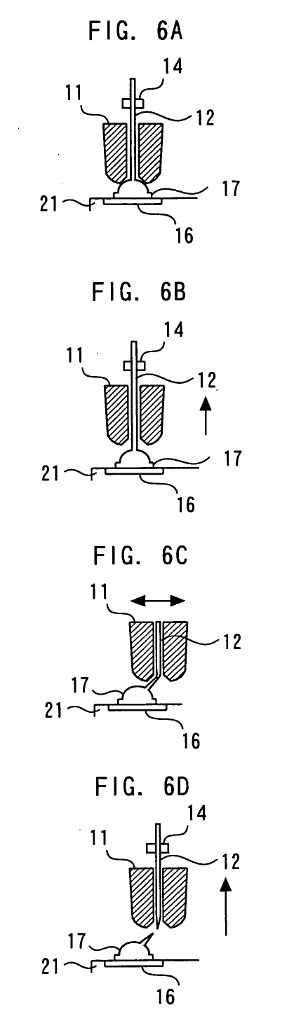

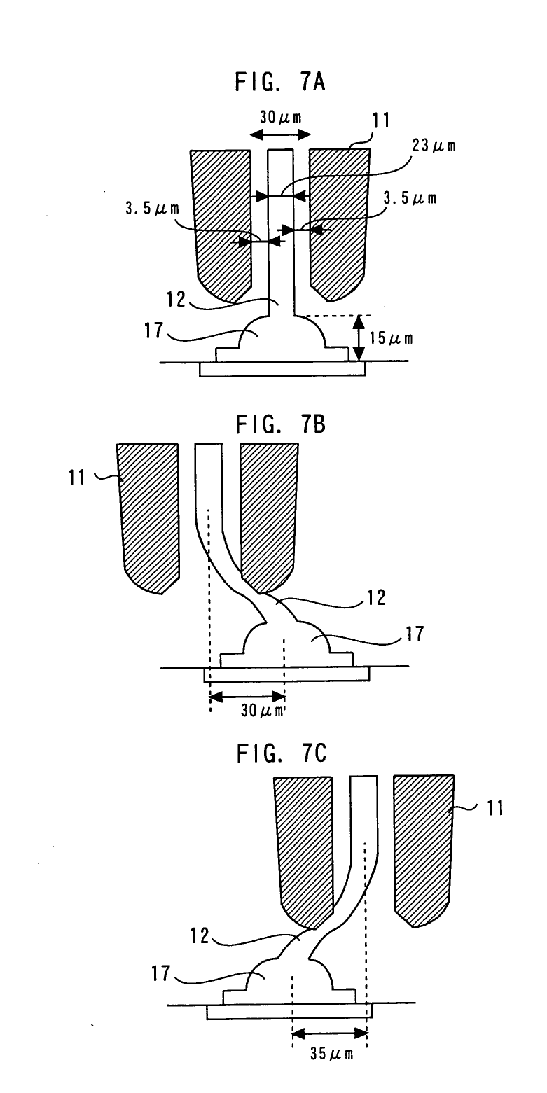

FIGS. 6A to 6D are sectional views showing a method of manufacturing a semiconductor device according to a third embodiment of the present invention. FIGS. 7A to 7C are enlarged sectional views showing the tip of the capillary.

A gold ball formed as a tip of goldwire 12 fed out from the capillary 11 is first joined on one Al pad 16 on the chip 21 to form one bump electrode 17, as shown in FIG. 6A. The capillary 11 is then lifted by 15 μm, as shown in FIG. 6B. This means that the capillary 11 retreats from the bump electrode 17 to a position above the bump electrode 17, since the height of the bump electrode is 15 μm. The sizes of the capillary 11 and the gold wire 12 used in this embodiment are as shown in FIG. 7A. The inside diameter of the capillary is 30 μm and the diameter of the gold wire 12 is 23 am.

Thereafter, the capillary 11 is reciprocatingly moved laterally, as shown in FIG. 6C. However, the amplitude of movement of the capillary 11 is set at least equal to or larger than the gap between the gold wire 12 and the inner wall surface of the capillary 11. More specifically, the gap between the gold wire 12 and the capillary 11 inner wall surface on one side of the gold wire 12 is 3.5 μm on average and the sum of the gaps on the opposite sides of the gold wire 12 is 7 μm since the diameter of the gold wire 12 is 23 μm and the inside diameter of the capillary is 30 μm. It is necessary that the movement amplitude be at least equal to or larger than the 3.5 μm gap between the gold wire 12 and the capillary 11 inner wall surface on one side of the gold wire 12. It is more preferable to set the movement amplitude to 7 μm or more corresponding to the sum of the gaps between the capillary 11 inner wall surface and the gold wire 12 in order to produce such sufficient stress in a portion of the gold wire 12 to be cut by tail cutting that the strength of the portion to be cut is reduced. Accordingly, the capillary 11 is moved, for example, by a distance of 30 μm in one direction, as shown in FIG. 7B, and is thereafter horizontally moved by a distance of 65 μm in the opposite direction, as shown in FIG. 7C. Stress is thereby produced in the portion of the gold wire 12 to be cut by tail cutting. In this way, the strength of the portion to be cut by tail cutting can be reduced. Also, the gold wire 12 can be cut off from the bump electrode 17 by being horizontally moved, depending on the extent of horizontal movement.

Thereafter, the gold wire 12 is cut by being pinched in the clamper 14 and pulled upward, as shown in FIG. 6D. Since the strength of the gold wire 12 is reduced by the reciprocating movement of the capillary 11, the reaction to this cutting of the gold wire 12 is reduced and the production of an S-shaped bend in the gold wire 12 and separation of the bump electrode 17 are limited.

Also, the capillary 11 is retreated above the bump electrode 17 before the reciprocating movement of the capillary 11 to prevent the bump electrode 17 from being damaged by contact between the capillary 11 and the bump electrode 17.

The capillary 11 may be laterally moved in circular motion instead of being laterally moved in reciprocating motion. Any other movement of the capillary 11 including a lateral movement as expressed in vector decomposition may alternatively be produced. The frequency of vibration and a means for moving the capillary 11 are not particularly specified. The amplitude of ultrasonic vibration is ordinarily 1 μm or less and it is difficult to obtain ultrasonic vibration with a sufficiently large amplitude as the movement of the capillary 11 for reducing the strength of the gold wire 12. In this embodiment, the above-described horizontal movement of the capillary 11 is produced by operating a motor as a motive power source while mechanically controlling the position of the motor.

### Fourth Embodiment

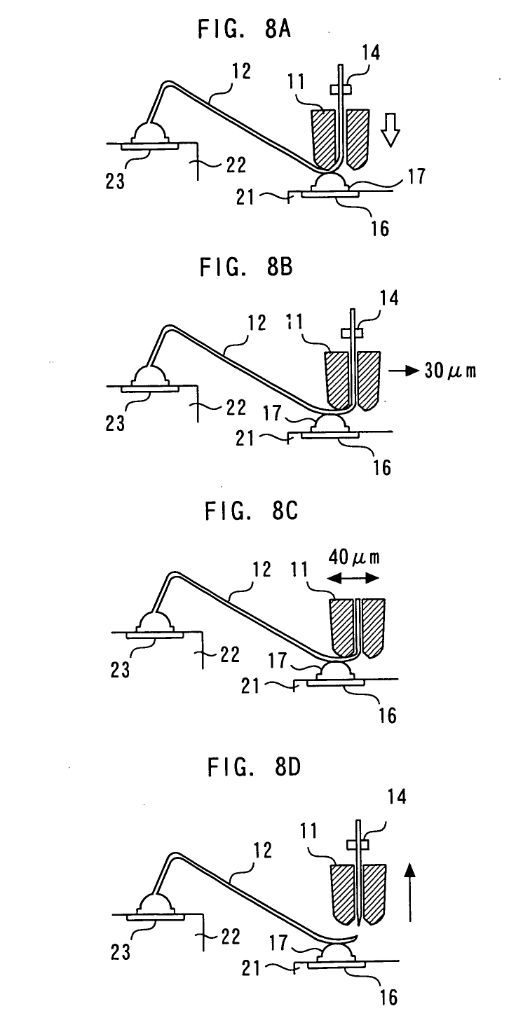

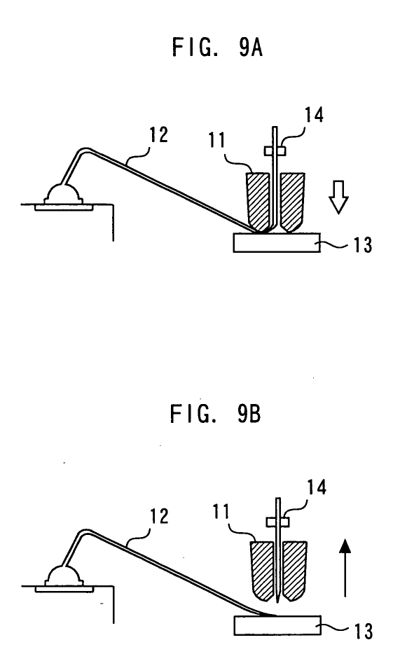

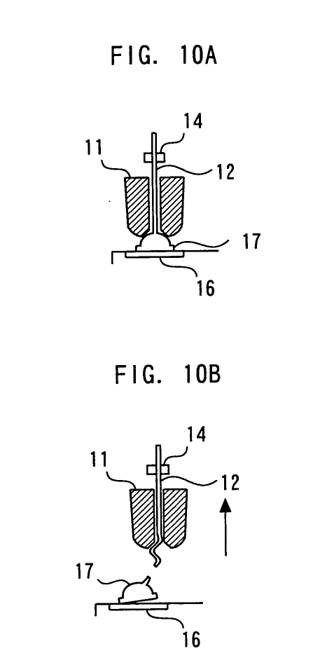

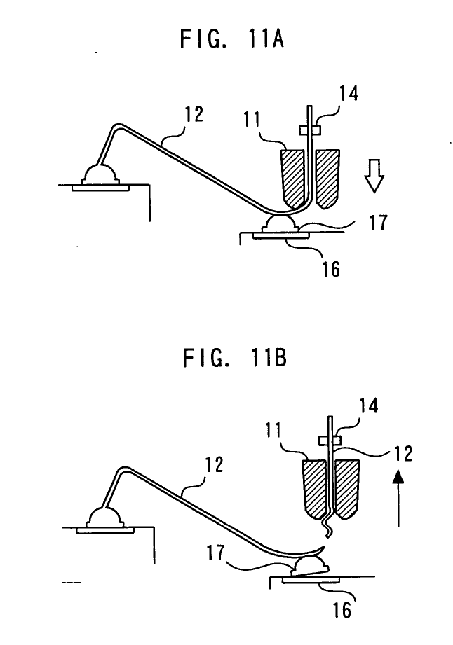

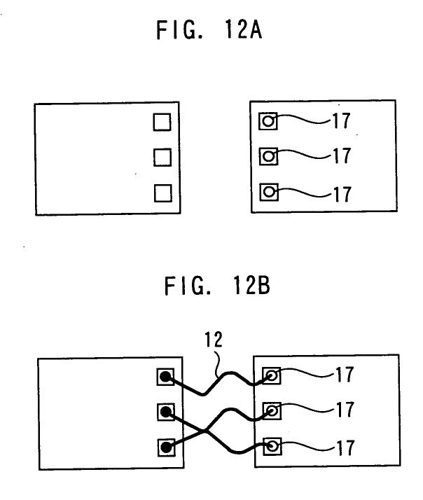

FIGS. 8A to 8D are sectional views showing a method of manufacturing a semiconductor device according to a fourth embodiment of the present invention.

A gold ball formed as a tip of gold wire 12 is first ball-bonded to one Al pad 23 on the chip 22 by using the capillary 11, and the gold wire 12 is thereafter stitch-bonded on the bump electrode 17 formed on the Al pad 16 on the chip 21, as shown in FIG. 8A. More specifically, the gold wire 12 is pressed against the bump electrode 17 for 10 ms by the capillary 11 while ultrasonic vibration is applied to the gold wire 12, thereby crushing the gold wire 12 and joining the gold wire 12 to the bump electrode 17.

Thereafter, the capillary 11 is retreated in the direction of loop advancement of the gold wire 12 by a distance equal to or larger than one-half of the amplitude of a lateral movement of the capillary 11 in a subsequent step, as shown in FIG. 8B. For example, the capillary 11 is horizontally moved by a distance of 30 μm.

Thereafter, the capillary 11 is laterally moved in reciprocating motion, as shown in FIG. 8C, as in the third embodiment 3. However, the amplitude of movement of the capillary 11 is set at least equal to or larger than the gap between the gold wire 12 and the inner wall surface of the capillary 11. More specifically, it is necessary that the movement amplitude be at least equal to or larger than the 3.5 μm gap between the gold wire 12 and the capillary 11 inner wall surface on one side of the gold wire 12. It is more preferable to set the movement amplitude to 7 μm or more corresponding to the sum of the gaps between the capillary 11 inner wall surface and the gold wire 12 in order to produce such sufficient stress in a portion of the gold wire 12 to be cut by tail cutting that the strength of the portion to be cut is reduced.

Thereafter, the gold wire 12 is cut by being pinched in the clamper 14 and pulled upward, as shown in FIG. 8D. Since the strength of the portion of the gold wire 12 to be cut is reduced by the reciprocating movement of the capillary 11, the reaction to this cutting of the gold wire 12 is reduced and the production of an S-shaped bend in the gold wire 12 and separation of the bump electrode 17 are limited. The gold wire 12 can also be cut by the reciprocating movement, depending on the amplitude of the reciprocating movement. If the gold wire 12 is cut in this way, the amount of S-shape bending in the gold wire 12 due to the reaction to cutting can be minimized.

Since before the reciprocating movement of the capillary 11 the capillary 11 is moved by a distance equal to or larger than one-half of the amplitude of the reciprocating movement away from the position at which stitch bonding has been started, i.e., the position at which the gold wire 12 has been brought into contact with the bump electrode 17, stress in portions of the gold wire 12 and the bump 17 joined to each other and stress in a root portion of the gold wire 12, produced during the reciprocating movement of the capillary 11, are reduced, thus preventing a considerable reduction in strength or breaking of the wire.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2005-91023, filed on Mar. 28, 2005 including specification, claims, drawings and summary, on which the Convention priority of the present application is based, are incorporated herein by reference in its entirety.

What is claimed is:

1. A method of manufacturing a semiconductor device comprising:
a step of preparing a first chip having a plurality of first pads and a second chip having a plurality of second pads;
a step of forming a first bump electrode on one of the plurality of first pads by a wire fed out from a capillary;
a step of forming a first wire electrically connecting one of the first bump electrode and one of the plurality of second pads by the wire fed out from the capillary after the step of forming the first bump electrode; and
a step of forming a second bump electrode on another of the plurality of first pads by the wire fed out from the capillary after the step of forming the first wire.

2. The method according to claim 1, wherein the step of forming the first wire includes a step of forming a metal ball as a tip of the wire fed out from the capillary, a step of bonding the metal ball to one of the plurality of second pads, and a step of feeding out from the capillary the wire extending from the metal ball and stitch-bonding a portion of the wire extending from the metal ball on the first bump electrode.

3. The method according to claim 1, wherein the step of forming the first bump electrodes includes a step of forming a metal ball as a tip of the wire fed out from the capillary, a step of bonding the metal ball to one of the plurality of pads, and a step of cutting above the metal ball the wire extending from the metal ball.

4. The method according to claim 1, further comprising, after the step of forming the second bump electrode, a step of forming a second wire electrically connecting another of the second bump electrode and another of the plurality of second pads by the wire fed out from the capillary.

5. A method of manufacturing a semiconductor device comprising:
a step of preparing a first chip having a plurality of first pads and a plurality of second pads arranged with a pitch smaller than a pitch with which the plurality of first pads are arranged, and a second chip having a plurality of third pads;
a step of forming a plurality of first bump electrodes on the plurality of first pads and a plurality of second bump electrodes on the plurality of second pads by a wire fed out from a capillary;
a step of forming a plurality of first wires electrically connecting one of the plurality of first bump electrodes and one of the plurality of third pads by the wire fed out from the capillary after the step of forming the plurality of first and second bump electrodes; and
a step of forming a plurality of second wires electrically connecting another of the plurality of second bump electrodes and another of the plurality of third pads by the wire fed out from the capillary after the step of forming the plurality of first wires.

6. A method of manufacturing a semiconductor device comprising:
a step of forming a bump electrode on a pad by a wire passed through a capillary;
a step of laterally moving the capillary at least with an amplitude equal to or larger than a gap between the wire and an inner wall surface of the capillary after the step of forming the bump electrode; and
a step of cutting the wire by pinching the wire in a damper and pulling the wire upward after the step of laterally moving the capillary.

7. The method according to claim 6, further comprising a step of retreating the capillary above the bump electrode before laterally moving the capillary.

8. A method of manufacturing a semiconductor device comprising:
a step of stitch-bonding a wire on a bump electrode by using a capillary;
a step of laterally moving the capillary at least with an amplitude equal to or larger than a gap between the wire and an inner wall surface of the capillary after the stitch bonding step; and
a step of cutting the wire by pinching the wire in a damper and pulling the wire upward after the step of laterally moving the capillary.

9. The method according to claim 8, further comprising a step of retreating the capillary from the position at which stitch bonding has been performed, in the direction of loop advancement of the wire, by a distance equal to or larger than one-half of the amplitude of the lateral movement of the capillary, before laterally moving the capillary.
